(19) United States
(12) Patent Application Publication
(10) Pub. No.: US 2025/0360799 A1
(43) Pub. Date: Nov. 27, 2025

(54) HYBRID POWER CONTROL DEVICE

(71) Applicants: Hyundai Motor Company, Seoul (KR); Kia Corporation, Seoul (KR)

(72) Inventors: Seung Woo CHOI, Hwaseong-Si (KR); Se Min Woo, Hwaseong-Si (KR); Byung Kwon Han, Hwaseong-Si (KR)

(73) Assignees: Hyundai Motor Company, Seoul (KR); Kia Corporation, Seoul (KR)

(21) Appl. No.: 18/945,131

(22) Filed: Nov. 12, 2024

(30) Foreign Application Priority Data
May 24, 2024 (KR) 10-2024-0067837

(51) Int. Cl. B60L 15/00; H05K 7/14

(52) U.S. Cl. CPC B60L 15/007; H05K 7/14329; B60L 2210/10

(57) ABSTRACT

A hybrid power control device which is lightweight by changing a material of a housing and has improved grounding performance, includes: a housing formed of a non-conductive material and including a grounding port on an external surface of the housing; and a plurality of grounding busbars disposed inside or outside the housing and including a first side connected directly or indirectly to the grounding port and a second side connected to a component mounted inside or outside the housing.

### CROSS-REFERENCE TO RELATED APPLICATIONS

The present application claims priority to Korean Patent Application No. 10-2024-0067837 filed on May 24, 2024, the entire contents of which is incorporated herein for all purposes by this reference.

### BACKGROUND OF THE PRESENT DISCLOSURE

### Field of the Present Disclosure

The present disclosure relates to a hybrid power control device which is made lightweight through changing a material of a housing and has improved grounding performance.

### Description of Related Art

Eco-friendly vehicles using a motor as a driving source, such as hybrid vehicles or electric vehicles, use a high-voltage battery as an energy source to drive the motor, an inverter providing power to the motor as a power conversion component and a low voltage DC-DC convertor (LDC) generating power of about 12V.

The inverter converts DC power of the high-voltage battery into 3-phase AC power between the motor and the high-voltage battery and provides the same to the motor, and the LDC (or converter) converts DC power of the high-voltage battery into 12V power and provides the same to electrical components of a vehicle.

A hybrid power control device may be configured by integrating the inverter, the converter, and the controller configured for controlling the inverter and the converter in a package form. The hybrid power control device includes a housing providing an interface for assembling internal components, such as the inverter and the converter, and protecting the components.

However, since the housing is formed of a conductive material, such as aluminum, the housing has excellent shielding and grounding performance, but may be disadvantageously heavy. Due thereto, the housing does not meet the goal of maximizing fuel efficiency required for eco-friendly vehicles. Furthermore, costs of housings formed of aluminum increase as a die casting method is applied and post-processing operations occur.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a hybrid power control device which is lightweight, by changing a material of a housing and secures grounding performance that has become insufficient due to change in materials.

According to an aspect of the present disclosure, a hybrid power control device includes: a housing formed of a non-conductive material and including a grounding port on an external surface of the housing; and a plurality of grounding busbars disposed inside or outside the housing and including a first side connected directly or indirectly to the grounding port and a second side connected to a component mounted inside or outside the housing.

The housing may include a first sidewall, a second sidewall, a third sidewall, a fourth sidewall and an upper surface connecting upper end portions of the first, second, third, and fourth sidewalls, and the grounding port may be disposed on the first sidewall.

The plurality of grounding busbars may include a first grounding busbar, wherein the first grounding busbar may be mounted on an external surface of the first sidewall, a first end portion thereof is fixed to the grounding port, and a second end portion thereof may be connected to a low-voltage DC-DC converter within the housing through the housing.

The first grounding busbar may include a molded portion molded with an insulating material, and the molded portion may include a sealing member covering a first through-hole of the housing through which the second end portion of the first grounding busbar passes and sealing a periphery of the first through-hole.

The plurality of grounding busbars may include a second grounding busbar, wherein the second grounding busbar may be mounted on an external surface of the first sidewall and may extend to the second sidewall adjacent to the first sidewall, one end portion thereof may be connected to the first grounding busbar, and the other end portion thereof may be connected to the low-voltage DC-DC converter through the housing.

The second grounding busbar may include a molded portion molded with an insulating material, and the molded portion may include a sealing member covering a second through-hole of the housing through which the second end portion of the second grounding busbar passes and sealing a periphery of the second through-hole.

The hybrid power control device may further include: an auxiliary grounding wire extending from the grounding port to an external surface of the third sidewall on the opposite side of the first sidewall.

The plurality of grounding busbars may include a third grounding busbar, wherein the third grounding busbar may be mounted on an external surface of the third sidewall, one end portion thereof may be connected to the auxiliary grounding wire, and the other end portion thereof may be branched in plural to include a first branch portion, a second branch portion, and a third branch portion.

A first connection portion for inputting voltage, a second connection portion for outputting voltage, and a mounting portion of a junction box for distributing a voltage may be provided outside the housing, wherein the first branch portion may be connected to the first connection portion, the second branch portion may be connected to the second connection portion, and the third branch portion may be connected to one side of the mounting portion.

The plurality of grounding busbars may include a fourth grounding busbar, wherein the fourth grounding busbar may be mounted on an external surface of the first sidewall, one end portion thereof is fixed to the grounding port, and the other end portion may be branched in plural to include a first branch portion, a second branch portion, and a third branch portion.

A first connection portion for inputting voltage, a second connection portion for outputting voltage, and a mounting portion of a junction box for distributing voltage may be provided outside the housing, wherein the first branch portion may be connected to the first connection portion, the second branch portion may be connected to the second connection portion, and the third branch portion may be connected to the other side of the mounting portion.

The plurality of grounding busbars may include a fifth grounding busbar, wherein the fifth grounding busbar may be mounted on an internal surface of the second sidewall, one end portion thereof may be connected to the other end portion of the second grounding busbar passing through the housing, and the other end portion thereof may be branched in plural to include a first branch portion, a second branch portion, and a third branch portion.

The first branch portion may be connected to a shielding plate in the housing, and the second branch portion may be connected to a switching unit of an inverter module in the housing.

The plurality of grounding busbars may include a sixth grounding busbar, wherein the sixth grounding busbar may be mounted on an internal surface of the third sidewall on the opposite side of the first sidewall, one end portion thereof may be connected to the third branch portion of the fifth grounding busbar, and the other end portion thereof may be connected to a capacitor in the housing.

The plurality of grounding busbars may include a seventh grounding busbar, wherein the seventh grounding busbar may be mounted on an external surface of the first sidewall and is located on the opposite side of the second grounding busbar with respect to the first grounding busbar, one end portion thereof may be connected to the first grounding busbar, and the other end portion thereof may be connected to a protruding portion of the low-voltage DC-DC converter exposed from the housing.

A cover may be coupled to lower end portions of the sidewalls.

The grounding port may be connected to a grounding wire for grounding by inducing flow of electricity.

An internal peripheral surface of the grounding port may include a thread, and a fixing screw may be connected to the grounding port, so that at least one of the plurality of grounding busbars and the grounding wire may be together connected and fixed to the grounding port.

The non-conductive material may include plastic.

The plastic may be a mixture of polyamide-based resin and 35 wt % of carbon filler.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF DRAWINGS

FIG. 1 is a perspective view exemplarily illustrating a hybrid power control device according to an exemplary embodiment of the present disclosure.

FIG. 2 is an exploded perspective view of FIG. 1.

FIG. 3 is an enlarged view exemplarily illustrating an arrangement of a first grounding busbar.

FIG. 4 is an enlarged view exemplarily illustrating an arrangement of a second grounding busbar.

FIG. 5 is an enlarged view exemplarily illustrating an arrangement of a third grounding busbar.

FIG. 6 is an enlarged view exemplarily illustrating an arrangement of a fourth grounding busbar.

FIG. 7 is an enlarged view exemplarily illustrating an arrangement of a fifth grounding busbar.

FIG. 8 is an enlarged view exemplarily illustrating an arrangement of a sixth grounding busbar.

FIG. 9 is an enlarged view exemplarily illustrating an arrangement of a seventh grounding busbar.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, the present disclosure is described in detail through drawings. When adding reference numerals to components in each drawing, it should be noted that identical components are provided the same reference numerals as much as possible although they are illustrated in different drawings.

In the present specification, vehicles refer to a variety of vehicles that move transported objects, such as people, animals, or goods, from a starting point to a destination. These vehicles are not limited to vehicles that run on roads or tracks.

In the present specification, the present disclosure is described using a hybrid vehicle or an electric vehicle as an example for convenience of description, but the present disclosure is not limited thereto.

Furthermore, terms, such as first, second, and third may be used to describe various components, but these components are not limited in order, size, location, or importance by terms, such as first, second, and third and named for the sole purpose of distinguishing one component from another.

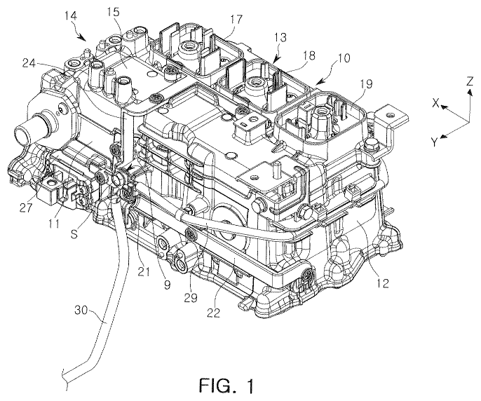

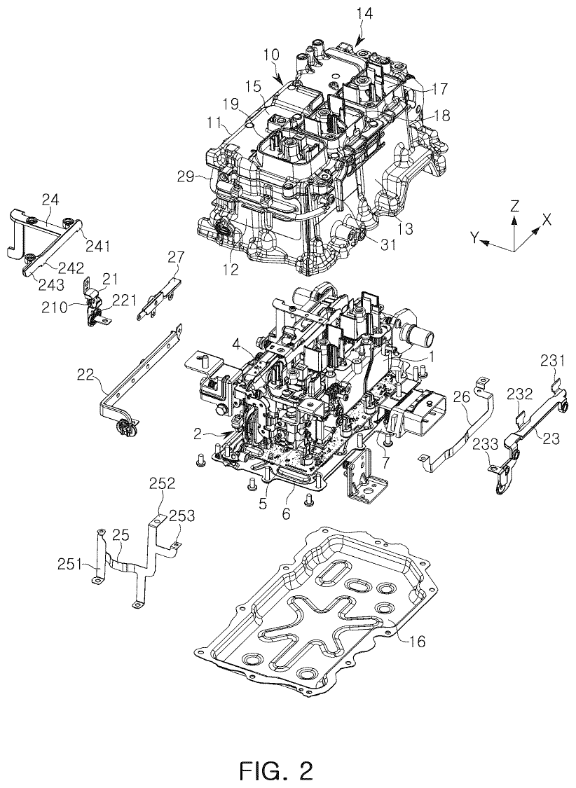

FIG. 1 is a perspective view exemplarily illustrating a hybrid power control device according to an exemplary embodiment of the present disclosure, and FIG. 2 is an exploded perspective view of FIG. 1.

A hybrid power control device according to an exemplary embodiment of the present disclosure may include a housing 10 and a plurality of grounding busbars 21, 22, 23, 24, 25, 26, and 27.

First, the hybrid power control device may include an inverter module 1 and a low voltage DC-DC convertor (LDC) 2 which are high-voltage components, and a gate board 5 and a control board 7, which are low-voltage components. Furthermore, the hybrid power control device may include a housing 10 and a cover 16 to accommodate these components.

In the housing 10, the inverter module 1, the LDC 2, the gate board 5, the control board 7, etc. may be appropriately disposed and accommodated to occupy a predetermined region in an internal space of the housing. For example, the inverter module, the LDC, the gate board, the control board, etc. may be sequentially mounted from top to bottom in an internal space of the housing, but the arrangement relationship is not limited thereto.

A power module including a cooler may be disposed on one side of the inverter module 1. The inverter module may include a power module, which is a switching element for power conversion, a capacitor, an inductor, etc.

The LDC 2 may include a power board, an inductor, a transformer, a diode, etc.

Furthermore, a shielding plate 6 may be disposed between the gate board 5 and the control board 7.

Since these components are already known, detailed descriptions of the components and operations thereof are omitted in the present specification.

The housing 10 may be formed to include a substantially box shape with an open bottom to enable maintenance and may include a plurality of sidewalls 11, 12, 13, and 14 extending in a height direction along the edge portion of the open bottom and an upper surface 15 connecting upper end portions of the sidewalls 11, 12, 13, and 14.

The plurality of sidewalls may include, for example, a first sidewall 11, a second sidewall 12, a third sidewall 13, and a fourth sidewall 14.

The upper surface 15 of the housing 10 may be provided with a first connection portion 17 for inputting (DC) high voltage from a battery and a second connection portion 18 for outputting high voltage to the motor. A connector for electrical connection may be connected to each connection portion.

Furthermore, the upper surface 15 of the housing 10 may be provided with a mounting portion 19 of a junction box for distribution of high voltage adjacent to the connection portions 17 and 18.

The arrangement of the first and second connection portions 17 and 18 and the junction box is not limited to the examples described above and illustrated.

The cover 16 may be coupled to the bottom portion of the housing 10 to block the internal space of the housing 10 from the outside thereof and prevent the intrusion of foreign matter thereinto.

The shape of the housing 10 and the arrangement of the cover 16 are not limited to the example illustrated above, and the housing 10 may be formed to have various shapes and a position of the cover may also change.

In the hybrid power control device according to an exemplary embodiment of the present disclosure, the housing 10 is formed of a non-conductive material to realize a lighter vehicle and reduce costs. For instance, plastic may be used as a non-conductive material.

For example, a plastic in which about 35% of carbon filler is mixed with polyamide (PA)-based resin may be selected as the material for the housing 10, but it is not limited thereto. When such a plastic material is employed, the housing may be injection-molded.

Furthermore, the cover 16 is formed of plastic to reduce weight.

With the high-voltage components and low-voltage components accommodated in the single housing 10, the cover 16 may be assembled and sealed at the bottom portion of the housing 10, allowing the hybrid power control device to form an integrated package.

The hybrid power control device configured in the present manner requires a ground that smoothly induces flow of electricity to maintain a stable operation. To the present end, the hybrid power control device may be connected to a vehicle body via a grounding wire 30.

The housing 10 may be provided with a grounding port 9 formed on an external surface of one sidewall, that is, the first sidewall 11. The grounding port 9 may include a hole shape and may have threads formed on an internal peripheral surface thereof. A fixing screw S may be connected to the grounding port 9, and at least one of the plurality of grounding busbars 21, 22, 23, 24, 25, 26, and 27 and the grounding wire 30 may be connected and fixed together to the grounding port by the fixing screw.

Here, the grounding wire 30 may be formed of a conductor of a highly conductive material, such as copper, aluminum, iron, etc. An external surface of the conductor may be covered with an insulator, such as resin or fiber, and ring portions 31 including a substantially annular shape may be formed at both end portions of the conductor. One end portion of the grounding wire 30 may be connected to the grounding port 9, and the other end portion thereof may be connected to the vehicle body.

The plurality of grounding busbars 21, 22, 23, 24, 25, 26, and 27 may be respectively disposed inside or outside the housing 10, so that one side may be directly or indirectly connected to the grounding port 9 of the housing. Furthermore, the other side of each grounding busbar may be connected to a component mounted inside or outside the housing, that is, a grounding object requiring grounding.

The plurality of grounding busbars may include, for example, a first grounding busbar 21, a second grounding busbar 22, a third grounding busbar 23, a fourth grounding busbar 24, and a fifth grounding busbar 25, a sixth grounding busbar 26, and a seventh grounding busbar 27.

The plurality of grounding busbars 21, 22, 23, 24, 25, 26, and 27 may be formed of a conductor of a highly conductive material, such as copper, especially, pure copper, to reduce power loss. The grounding busbar may have a plate shape including an approximately rectangular cross-section and a predetermined thickness.

The grounding busbar disposed and externally exposed of the housing 10 may include a molded portion which is at least partially molded with a material, such as resin for insulation.

Optionally, the grounding busbar may include a bent portion bent at a predetermined angle or a split branch portion. Furthermore, an approximately annular ring portion may be formed at an end portion of the grounding busbar for easy connection and fixation, so that the fixing screw S may be inserted into and pass through the ring portion and then fastened to the housing 10.

In the present specification, unless otherwise stated, connection and fixation of the grounding busbar may be performed by fastening the fixing screw S. However, without being limited thereto, the grounding busbar may be selectively connectable to and fixed to the housing or a grounding object by any other method, such as welding or soldering.

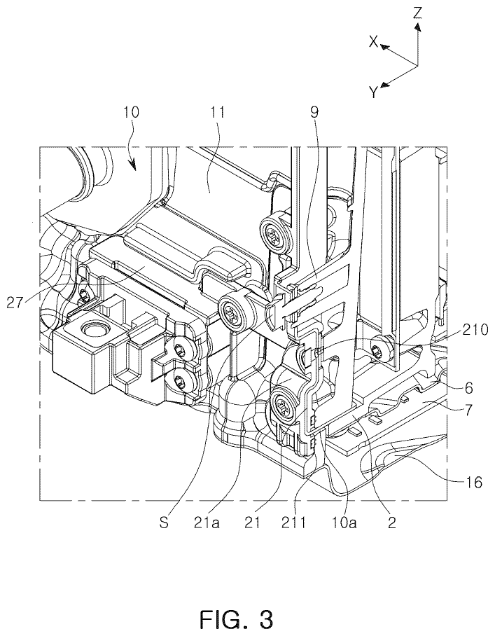

FIG. 3 is an enlarged view exemplarily illustrating the arrangement of the first grounding busbar.

The first grounding busbar 21 may be mounted on an external surface of the first sidewall 11 of the housing 10 in which the grounding port 9 is formed. In FIG. 3, the grounding wire 30 is omitted for convenience of illustration.

In the first grounding busbar 21, a ring portion at one end portion thereof may be located to be aligned with the grounding port 9 and may be fixed to the grounding port by the fixing screw S together with the grounding wire 30, and the other end portion thereof may be connected to the LDC 2 through the housing 10. For example, the ring portion of the other end portion may be fixed to the first sidewall 11 of the housing with a fixing screw along with the LDC plate.

The first grounding busbar 21 may be formed to include a plurality of bent portions for mounting and penetration, and since the first grounding busbar 21 is disposed outside the housing 10, the first grounding busbar 21 may include a molded portion 21a. The molded portion 21a may include a sealing member 211 covering a first through-hole 10a of the housing 10 through which the other end portion passes and sealing the periphery of the first through-hole 10a.

The first grounding busbar 21 may be directly connected to the grounding wire 30 and connected to the LDC 2, so that, together with the LDC, a cooler cover, the power board, the transformer, the gate board 5, and the shielding plate 6 may be grounded to the vehicle body.

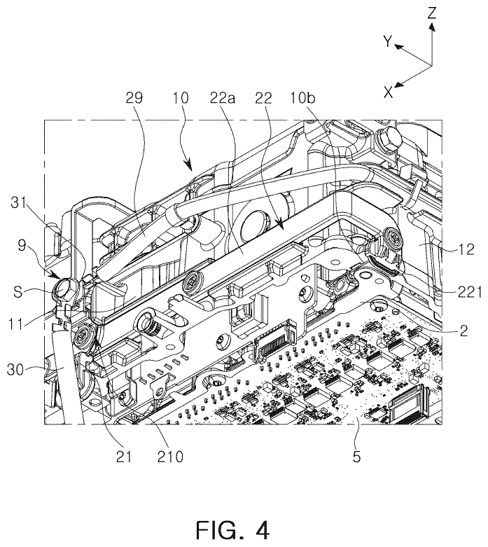

FIG. 4 is an enlarged view exemplarily illustrating the arrangement of the second grounding busbar.

The second grounding busbar 22 may be mounted on an external surface of the first sidewall 11 on which the grounding port 9 is formed in the housing 10 and may extend to the second sidewall 12 adjacent to the first sidewall.

One end portion of the second grounding busbar 22 may be connected to the first grounding busbar 21, and the other end portion thereof may be connected to the LDC 2 through the housing 10.

For example, in the second grounding busbar 22, the ring portion at one end portion may be located to be aligned with a connection hole 210 formed in the middle portion of the first grounding busbar 21 and may be fixed to the first sidewall 11 of the housing 10 by the fixing screw S. Furthermore, the ring portion at the other end portion may be fixed to the second sidewall 12 of the housing by a fixing screw along with the LDC plate.

The second grounding busbar 22 may include a plurality of bent portions for mounting and penetration, and since the second grounding busbar 22 is disposed outside the housing 10, the second grounding busbar 22 may include a molded portion 22a. The molded portion may include a sealing member 221 covering a second through-hole 10b of the housing 10 through which the other end portion passes and sealing the periphery of the second through-hole.

The second grounding busbar 22 may be indirectly connected to the grounding wire 30 via the first grounding busbar 21 and may be connected to the LDC 2, so that, together with the LDC, the cooler cover, the power board, the transformer, the gate board 5, shielding plate 6, and the like may be grounded to the vehicle body.

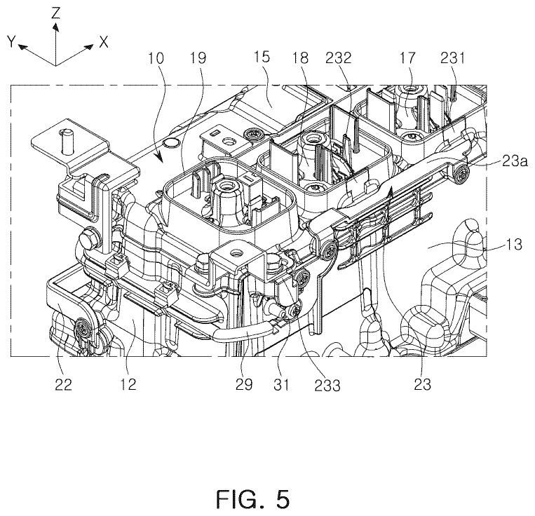

FIG. 5 is an enlarged view exemplarily illustrating the arrangement of the third grounding busbar.

The third grounding busbar 23 may be mounted on an external surface of the third sidewall 13 in the housing 10 on the opposite side of the first sidewall 11 in which the grounding port 9 is formed. To the present end, the hybrid power control device according to an exemplary embodiment of the present disclosure may further include an auxiliary grounding wire 29 extending from the grounding port to the external surface of the third sidewall on the opposite side thereof.

The auxiliary grounding wire 29, similarly to the grounding wire 30, may be formed of a conductor of a highly conductive material, such as copper, aluminum, iron, etc. An external surface of the conductor may be covered with an insulator, such as resin or fiber. Approximately annular ring portions 31 may be formed at both end portions of the conductor.

In the third grounding busbar 23, the ring portion at one end portion may be located to be aligned with the ring portion 31 of the auxiliary grounding wire 29 and may be fixed to the third sidewall 13 of the housing 10 by the fixing screw S together with the auxiliary grounding wire.

The third grounding busbar 23 may be branched in plural to include a first branch portion 231, a second branch portion 232, and a third branch portion 233. The first branch portion 231 may be connected to the first connection portion 17 disposed outside the housing 10, the second branch portion 232 may be connected to the second connection portion 18, and the third branch portion 233 may be connected to on one side of the mounting portion 19 of the junction box.

Here, the junction box, although not illustrated in the drawing, may include a separate connection conductor, and when mounted on the mounting portion 19 of the housing 10, the junction box may be electrically connected to the third branch portion 233 of the third grounding busbar 23 via the connection conductor.

The third grounding busbar 23 may include a plurality of bent portions for mounting, branching, and connection, and since the third grounding busbar 23 is disposed outside the housing 10, the third grounding busbar 23 may include a molded portion 23a.

The third grounding busbar 23 may be indirectly connected to the grounding wire 30 via the auxiliary grounding wire 29 and may be connected to the first connection portion 17, the second connection portion 18, and the mounting portion 19 of the junction box together, so that connectors connected to the first connection portion and the second connection portion and the junction box may be grounded to the vehicle body.

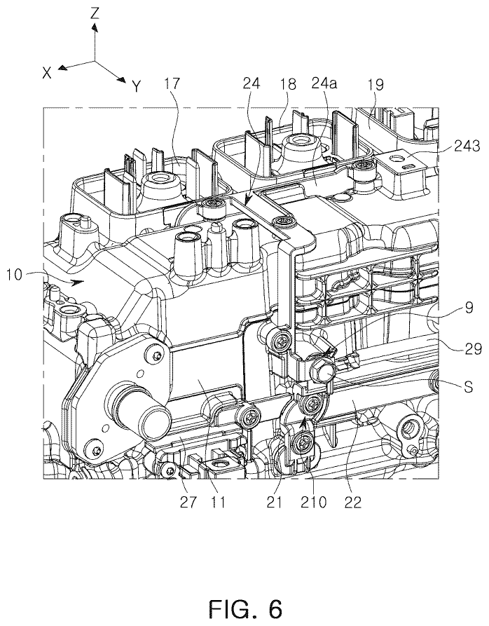

FIG. 6 is an enlarged view exemplarily illustrating the arrangement of the fourth grounding busbar.

The fourth grounding busbar 24 may extend from the first sidewall 11 in which the grounding port 9 is formed in the housing 10 to the upper surface 15 of the housing and may be mounted on the external surface of the housing 10.

In the fourth grounding busbar 24, the ring portion at one end portion may be located to be aligned with the grounding port 9 and may be fixed to the grounding port by the fixing screw S together with one end portion of the first grounding busbar 21 and the grounding wire 30.

The fourth grounding busbar 24 may extend to the upper surface 15 of the housing 10 and may be branched in plural to include a first branch portion 241, a second branch portion 242, and a third branch portion 243. The first branch portion 241 may be connected to the first connection portion 17 disposed outside the housing, the second branch portion 242 may be connected to the second connection portion 18, and the third branch portion 243 may be connected to the other side of the mounting portion 19 of the junction box.

The fourth grounding busbar 24 may include a plurality of bent portions for mounting, branching, and connection, and since the fourth grounding busbar 24 is disposed outside the housing, the fourth grounding busbar 24 may include a molded portion 24a.

The fourth grounding busbar 24 may be directly connected to the grounding wire 30 and may be connected together to the first connection portion 17, the second connection portion 18, and the mounting portion 19 of the junction box, so that connectors connected to the first connection portion and the second connection portion and the junction box may be grounded to the vehicle body.

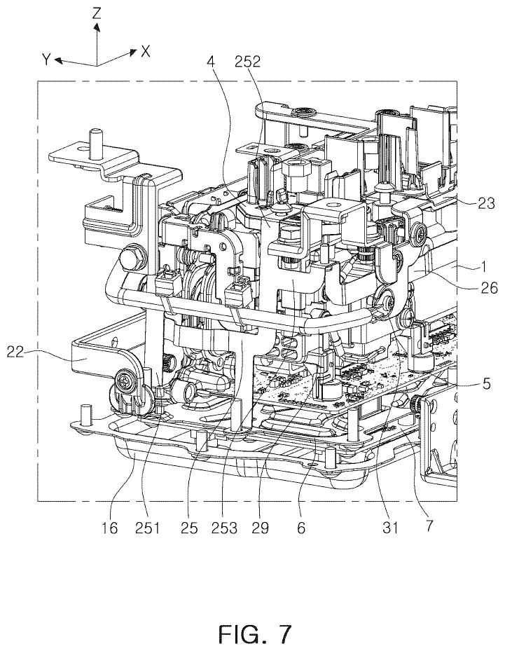

FIG. 7 is an enlarged view exemplarily illustrating the arrangement of the fifth grounding busbar.

The fifth grounding busbar 25 may be mounted on the internal surface of the second sidewall 12 adjacent to the first sidewall 11 on which the grounding port 9 is formed in the housing 10 and extend to the upper surface 15 of the housing. In FIG. 7, the housing is omitted.

In the fifth grounding busbar 25, the ring portion at one end portion may be located to be aligned with the ring portion at the other end portion of the second grounding busbar 22 passing through the housing 10 and may be fixed to the second sidewall 12 of the housing by the fixing screw S together with the second grounding busbar to be connected to the second grounding busbar.

The fifth grounding busbar 25 may be branched in plural to include a first branch portion 251, a second branch portion 252, and a third branch portion 253. The first branch portion may be connected to the shielding plate 6, and the second branch portion may be connected to a DC switching unit 4 of the inverter module 1. The third branch portion may be connected to the sixth grounding busbar 26.

The end portion of the first branch portion 251 may be fixed to the second sidewall 12 of the housing 10 by the fixing screw S together with the shielding plate 6. The second branch portion 252 may extend to the upper surface 15 of the housing and be connected to the switching unit 4.

The fifth grounding busbar 25 may be formed to include a plurality of bent portions for mounting, branching, and connection.

The fifth grounding busbar 25 may be indirectly connected to the grounding wire 30 via the first grounding busbar 21 and the second grounding busbar 22 and may be connected to the shielding plate 6 and the switching unit, so that the shielding plate, the switching unit, the control board 7, and the like may be grounded to the vehicle body.

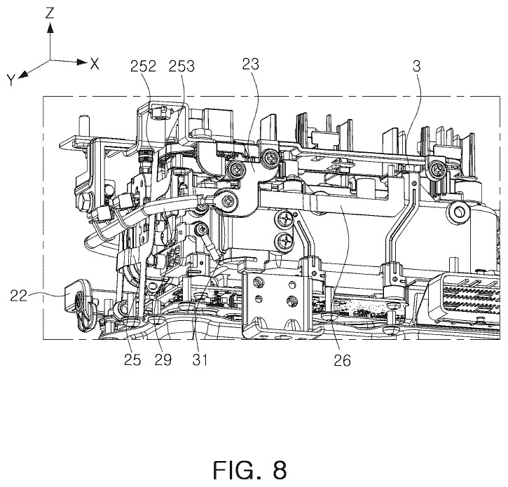

FIG. 8 is an enlarged view exemplarily illustrating the arrangement of the sixth grounding busbar.

The sixth grounding busbar 26 may be mounted on an internal surface of the third sidewall 13 on the opposite side of the first sidewall 11 in which the grounding port 9 is formed in the housing 10 and may extend to the upper surface 15 of the housing. In FIG. 8, the housing is omitted.

In the sixth grounding busbar 26, the ring portion at one end portion may be located to be aligned with the ring portion formed in the third branch portion 253 of the fifth grounding busbar 25 and may be fixed to a corner portion between the third sidewall 13 and the second sidewall 12 by the fixing screw S together with the fifth grounding busbar to be connected to the second grounding busbar. The other end portion may be connected to a capacitor 3 for a condenser in the housing 10. For example, the ring portion of the other end portion may be fixed to the upper surface 15 of the housing by a fixing screw along with the capacitor.

The sixth grounding busbar 26 may be formed to include a plurality of bent portions for mounting and connection.

The sixth grounding busbar 26 may be indirectly connected to the grounding wire 30 via the first grounding busbar 21, the second grounding busbar 22, and the fifth grounding busbar 25 and may be connected to the capacitor 3, so that the capacitor may be grounded to the vehicle body.

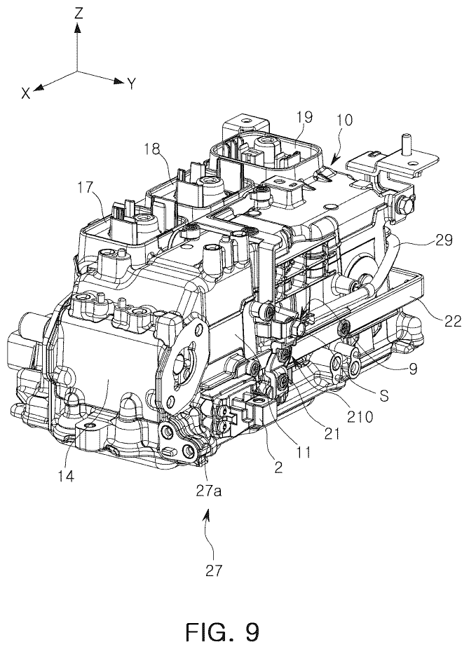

FIG. 9 is an enlarged view exemplarily illustrating the arrangement of the seventh grounding busbar.

The seventh grounding busbar 27 may be mounted on the external surface of the first sidewall 11 on which the grounding port 9 is formed in the housing 10 and may be located on the opposite side of the second grounding busbar 22 based on the first grounding busbar 21.

One end portion of the seventh grounding busbar 27 may be connected to the first grounding busbar 21, and the other end portion may be connected to a protruding portion of the LDC 2 exposed from the housing.

For example, in the seventh grounding busbar 27, the ring portion at one end portion may be located to be aligned with the connection hole 210 formed in the middle portion of the first grounding busbar 21 and may be fixed to the first sidewall 11 of the housing 10 by the fixing screw S. Furthermore, the ring portion at the other end portion may be fixed to a positive (+) side of the LDC by a fixing screw.

The seventh grounding busbar 27 may include a bent portion formed for mounting and connection, and since the seventh grounding busbar 27 is disposed outside the housing 10, the seventh grounding busbar 27 may include a molded portion 27a.

The seventh grounding busbar 27 may be indirectly connected to the grounding wire 30 via the first grounding busbar 21 and may be connected to the LDC 2, so that the LDC may be grounded to the vehicle body.

Meanwhile, the present applicant conducted a test to compare the performance of the hybrid power control device including a housing formed of aluminum according to the related art with the performance of the hybrid power control device including the housing 10 formed of plastic according to an exemplary embodiment of the present disclosure. As the plastic housing material, a mixture of polyamide-based resin and about 35 wt % of carbon filler was adopted.

Antennae were internally disposed within both hybrid power control devices and the applied electric fields were measured to confirm the shielding effects, and here, it was confirmed that the housings of both hybrid power control devices had equivalent noise shielding performance in the entire frequency range.

Next, a motor was connected to the hybrid power control device according to an exemplary embodiment of the present disclosure, power was applied to operate the motor and the hybrid power control device, and then contact resistance of the ground and conduction sound were measured. Because a plurality of grounding busbars 21, 22, 23, 24, 25, 26, and 27 formed of conductive material connect the components or circuits within the housing 10 and the vehicle body, noise shielding performance at ground may be secured, confirming that the hybrid power control device of the present disclosure satisfies the design requirements.

Therefore, the hybrid power control device according to an exemplary embodiment of the present disclosure may implement grounding of the high-voltage circuit by arranging the grounding busbars around the housing 10 and connecting the corresponding grounding busbars to components within the housing.

As described above, according to the exemplary embodiment of the present disclosure, by changing the material to plastic and manufacturing the housing by injection-molding, the weight of the vehicle may be reduced, and since post-processing is unnecessary compared to the existing die casting method, costs may be reduced.

The above description is merely illustrative of the technical idea of the present disclosure, and various modifications and changes may be made by those skilled in the art without departing from the essential characteristics of the present disclosure.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A hybrid power control apparatus comprising:
a housing formed of a non-conductive material and including a grounding port on an external surface of the housing; and
a plurality of grounding busbars disposed inside or outside the housing and including a first side connected directly or indirectly to the grounding port and a second side connected to a component mounted inside or outside the housing.

2. The hybrid power control apparatus of claim 1,
wherein the housing includes a first sidewall, a second sidewall, a third sidewall, a fourth sidewall and an upper surface connecting upper end portions of the first, second, third, and fourth sidewalls, and
wherein the grounding port is disposed on the first sidewall.

3. The hybrid power control apparatus of claim 2,
wherein the plurality of grounding busbars include a first grounding busbar, and
wherein the first grounding busbar is mounted on an external surface of the first sidewall, a first end portion of the first grounding busbar is fixed to the grounding port, and a second end portion of the first grounding busbar is connected to a low-voltage DC-DC converter within the housing through the housing.

4. The hybrid power control apparatus of claim 3,
wherein the first grounding busbar includes a molded portion molded with an insulating material, and
wherein the molded portion of the first grounding busbar includes a sealing member covering a first through-hole of the housing through which the second end portion of the first grounding busbar passes and sealing a periphery of the first through-hole.

5. The hybrid power control apparatus of claim 3,
wherein the plurality of grounding busbars include a second grounding busbar, and
wherein the second grounding busbar is mounted on the external surface of the first sidewall and extends to the second sidewall adjacent to the first sidewall, a first end portion of the second grounding busbar is connected to the first grounding busbar, and a second end portion of the second grounding busbar is connected to the low-voltage DC-DC converter through the housing.

6. The hybrid power control apparatus of claim 5,
wherein the second grounding busbar includes a molded portion molded with an insulating material, and
wherein the molded portion of the second grounding busbar includes a sealing member covering a second through-hole of the housing through which the second end portion of the second grounding busbar passes and sealing a periphery of the second through-hole.

7. The hybrid power control apparatus of claim 2, further including an auxiliary grounding wire extending from the grounding port to an external surface of the third sidewall on an opposite side of the first sidewall.

8. The hybrid power control apparatus of claim 7,
wherein the plurality of grounding busbars include a third grounding busbar, and
wherein the third grounding busbar is mounted on an external surface of the third sidewall, a first end portion of the third grounding busbar is connected to the auxiliary grounding wire, and a second end portion of the third grounding busbar is branched in plural to include a first branch portion, a second branch portion, and a third branch portion.

9. The hybrid power control apparatus of claim 8,
wherein a first connection portion for inputting voltage, a second connection portion for outputting voltage, and a mounting portion of a junction box for distributing voltage are provided outside the housing,
wherein the first branch portion is connected to the first connection portion,
wherein the second branch portion is connected to the second connection portion, and
wherein the third branch portion is connected to a first side of the mounting portion.

10. The hybrid power control apparatus of claim 2,
wherein the plurality of grounding busbars include a fourth grounding busbar, and
wherein the fourth grounding busbar is mounted on an external surface of the first sidewall, a first end portion of the fourth grounding busbar is fixed to the grounding port, and a second end portion of the fourth grounding busbar is branched in plural to include a first branch portion, a second branch portion, and a third branch portion.

11. The hybrid power control apparatus of claim 10,
wherein a first connection portion for inputting voltage, a second connection portion for outputting voltage, and a mounting portion of a junction box for distributing voltage are provided outside the housing,
wherein the first branch portion is connected to the first connection portion,
wherein the second branch portion is connected to the second connection portion, and
wherein the third branch portion is connected to a second side of the mounting portion.

12. The hybrid power control apparatus of claim 5,
wherein the plurality of grounding busbars include a fifth grounding busbar, and
wherein the fifth grounding busbar is mounted on an internal surface of the second sidewall, a first end portion of the fifth grounding busbar is connected to the second end portion of the second grounding busbar passing through the housing, and a second end portion of the fifth grounding busbar is branched in plural to include a first branch portion, a second branch portion, and a third branch portion.

13. The hybrid power control apparatus of claim 12,
wherein the first branch portion is connected to a shielding plate in the housing, and
wherein the second branch portion is connected to a switching unit of an inverter module in the housing.

14. The hybrid power control apparatus of claim 12,
wherein the plurality of grounding busbars include a sixth grounding busbar, and
wherein the sixth grounding busbar is mounted on an internal surface of the third sidewall on an opposite side of the first sidewall, a first end portion of the sixth grounding busbar is connected to the third branch portion of the fifth grounding busbar, and a second end portion of the sixth grounding busbar is connected to a capacitor in the housing.

15. The hybrid power control apparatus of claim 5,
wherein the plurality of grounding busbars include a seventh grounding busbar, and
wherein the seventh grounding busbar is mounted on the external surface of the first sidewall and is located on an opposite side of the second grounding busbar with respect to the first grounding busbar, a first end portion of the seventh grounding busbar is connected to the first grounding busbar, and the second end portion of the seventh grounding busbar is connected to a protruding portion of the low-voltage DC-DC converter exposed from the housing.

16. The hybrid power control apparatus of claim 2, wherein a cover is coupled to lower end portions of the first, second, third and fourth sidewalls.

17. The hybrid power control apparatus of claim 1, wherein the grounding port is connected to a grounding wire for grounding by inducing flow of electricity.

18. The hybrid power control apparatus of claim 17, wherein an internal peripheral surface of the grounding port includes a thread, and a fixing screw is connected to the grounding port, so that at least one of the plurality of grounding busbars and the grounding wire are together connected and fixed to the grounding port.

19. The hybrid power control apparatus of claim 1, wherein the non-conductive material includes plastic.

20. The hybrid power control apparatus of claim 19, wherein the plastic is a mixture of polyamide-based resin and 35 wt % of carbon filler.
